(19) United States
(12) Patent Application Publication
(10) Pub. No.: US 2016/0242324 A1
(43) Pub. Date: Aug. 18, 2016

(54) CONTAINER-TYPE DATA CENTER

(71) Applicant: DELTA ELECTRONICS, INC., Taoyuan County (TW)

(72) Inventors: Peng-Yuan CHEN, Taoyuan County (TW); Ming-Feng KANG, Taoyuan County (TW); Chia-Yi LIN, Taoyuan County (TW)

(21) Appl. No.: 14/838,432

(22) Filed: Aug. 28, 2015

(30) Foreign Application Priority Data
Feb. 13, 2015 (TW) 104104982

(51) Int. Cl. H05K 7/20

(52) U.S. Cl. CPC H05K 7/20745; H05K 7/20754

(57) ABSTRACT

A container-type data center includes an elongate container and a longitudinal rack row in the elongate container. The elongate container includes side walls, and the longitudinal rack row is arranged longitudinally in the elongate container. A cold aisle and a hot aisle are respectively formed between each of two sides of the server rack row and a corresponding one of the two side walls. The longitudinal rack row forms a single communication channel communicating the cold aisle with the hot aisle. The longitudinal rack row includes a server rack and an air conditioner rack. The communication channel allows staff to move between the cold aisle and the hot aisle and thus prevents air circulation from being effected by ambient environment due to entry and exit of the staff.

### BACKGROUND

1. Technical Field

The present invention relates to a container-type data center and, in particular, to a container-type data center provided therein with a single communication channel communicating a cold aisle with a hot aisle.

2. Related Art

A conventional container-type data center generally has three different types, i.e. a single-longitudinal-row type, a two-longitudinal-row type, or a multiple-transverse-column type. In the two-longitudinal-row type, the container-type data center includes two rows of racks arranged along two side walls of a container. A cold aisle is formed between the two rows of the racks, and two hot aisles are formed between each of the two rows and a respective one of the two side walls. However, such configuration needs a larger space, so cannot be applied to a standard container.

The single-longitudinal-row type configuration and the multiple-transverse-row type configuration can be applied to the standard container. However, the drawback is that a cold aisle is separated from the hot aisle, so each cold aisle or each hot aisle needs a maintenance door for entry and exit of maintenance staff. The temperature, humidity, and air circulation in the container are influenced by the ambient environment due to frequent entry and exit of the maintenance staff.

In view of the foregoing, the inventor made various studies to overcome the above-mentioned problems to realize the improvements, on the basis of which the present invention is accomplished.

### BRIEF SUMMARY

The present invention provides a container-type data center provided therein with a single communication channel communicating a cold aisle with a hot aisle.

The present invention provides a container-type data center comprising an elongate container and a single longitudinal rack row disposed in the elongate container. The elongate container includes two side walls, the longitudinal rack row is arranged longitudinally in the elongate container, and a cold aisle and a hot aisle are respectively formed between each of two sides of the single longitudinal rack row and a corresponding one of the two side walls. The longitudinal rack row forms a communication channel communicating the cold aisle with the hot aisle, and the longitudinal rack row includes at least one server rack and at least one air conditioner rack.

In the container-type data center according to the present invention, the communication channel communicates the cold aisle with the hot aisle, thereby preventing that maintenance staff frequently opens and close a maintenance door for maintenance, so the air circulation is prevented from being effected by the ambient environment. Therefore, efficient space planning can be acquired in a limited space to facilitate better management on the air-circulation field for heat dissipation and to allow easy maintenance.

### BRIEF DESCRIPTION OF THE DRAWINGS

FIG. 1 is a schematic configuration view of a container-type data center according to a first embodiment of the present invention.

FIG. 2 is a schematic configuration view of a container-type data center according to a second embodiment of the present invention.

FIG. 3 is a schematic configuration view of a container-type data center according to a third embodiment of the present invention.

FIG. 4 is a schematic configuration view of a container-type data center according to a fourth embodiment of the present invention.

### DETAILED DESCRIPTION

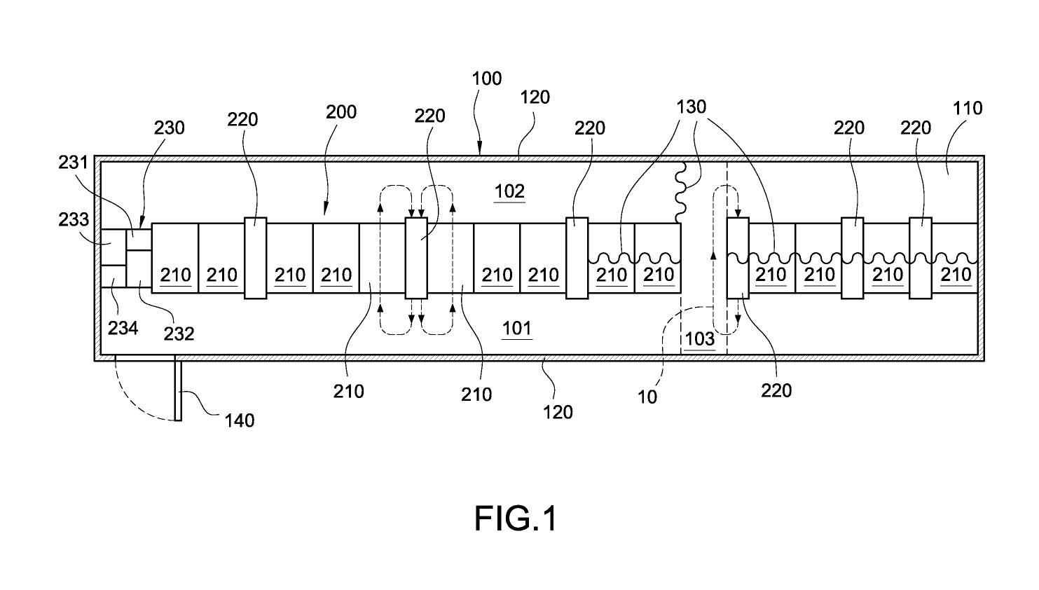

Referring to FIG. 1, a first embodiment of the present invention provides a container-type data center which comprises an elongate container 100 and a single longitudinal rack row 200 disposed in the elongate container 100.

According to the present embodiment, the elongate container 100 is preferably a standard-sized container; however, the present invention is not limited thereto, so the standard-sized container may be altered partially as required. The elongate container 100 includes a base 110 and two side walls 120. The base 110 is made of metal and has a flat rectangular shape. The base 110 is disposed horizontally to support the longitudinal rack row 200. Each of the side walls 120 is a rectangular metallic plate and disposed vertically on a respective long side of the base 110, so that the side walls 120 are disposed parallel to and spaced from each other. A top of the elongate container 100 is closed, and two ends of the elongate container 100 can be closed by metallic plates or container doors; however, the present invention is not limited thereto.

The longitudinal rack row 200 is disposed on the base 110 of the elongate container 100 and is a single row disposed along a longitudinal direction of the elongate container 100. Two ends of the longitudinal rack row 200 extend to two ends of the elongate container 100 respectively. Each of two sides of the longitudinal rack row 200 is spaced from a corresponding one of the two side walls 120 of the elongate container 100, and a cold aisle 101 and a hot aisle 102 are respectively formed between each of the two sides of the longitudinal rack row 200 and a corresponding one of the two side walls 120. A single communication channel 103 is formed in a middle portion of the longitudinal rack row 200. The cold aisle 101 and the hot aisle 102 are separated from each other, and the cold aisle 101 communicates with the hot aisle 102 only via the communication channel 103. A top of the longitudinal rack row 200 can extend to the top of the elongate container 100. An isolation structure 130 is disposed in a gap between the top of the longitudinal rack row 200 and the top of the elongate container 100. The isolation structure 130 separates the air in the cold aisle 101 from the air in the hot aisle 102. The isolation structure 130 is preferably a partition screen; however, the present invention is not limited thereto, and the isolation structure 130 may be, for example, a partition plate.

The longitudinal rack row 200 includes at least one server rack 210 and at least one air conditioner rack 220. In the present embodiment, the longitudinal rack row 200 includes a plurality of the server racks 210 and a plurality of the air conditioner racks 220 disposed between the server racks 210 and spaced from each other. A heat dissipation fan (not illustrated) is disposed in each of the server racks 210 for drawing in air from a front side of the server rack 210 to cool the server rack 210 and exhausting heated air from a rear side of the server rack 210. The front side of each of the server racks 210 is disposed in the cold aisle 101 and the rear side of each of the server racks 210 is disposed in the hot aisle 102. The air conditioner rack 220 is configured to draw in from the hot aisle 102 the heated air exhausted out of the server rack 210, cool the heated air, and exhaust the cooled air to the cold aisle 101 for the server rack 210 to draw in the cooled air to cool the server rack 210.

In the present embodiment, the air conditioner rack 220, most adjacent to the communication channel 103 in the elongate container 100, exhausts the cooled air to the cold aisle 101. The cooled air exhausted out of the air conditioner rack 220 flows back to the hot aisle 102 through the communication channel 103 and is again drawn into the air conditioner rack 220 to form an isolation flow field 10. The isolation flow field 10 is configured to separate the cooled air in the cold aisle 101 from the heated air in the hot aisle 102, thereby preventing that the cooled air in the cold aisle 101 directly contacts the heated air in the hot aisle 102 to perform heat exchange, and thus maintaining the air circulation between the cold aisle 101 and the hot aisle 102. In order to prevent a “dead corner” where there is no air circulation or inferior air circulation, the location of the air conditioner rack 220 needs to be arranged according to the entire heat dissipation requirement in the elongate container 100. In the event that the communication channel 103 cannot be disposed adjacent to the air conditioner rack 220, an isolation structure 130 can be disposed in the communication channel 103, and such that the isolation structure 130 separates the cooled air in the cold aisle 101 from the heated air in the hot aisle 102. The isolation structure 130 can be disposed at a common boundary between the communication channel 103 and the hot aisle 102 or can be disposed at a common boundary between the communication channel 103 and the cold aisle 101. In the present embodiment, the isolation structure 130 can be a partition screen; however, the present invention is not limited thereto.

According to the present invention, the longitudinal rack row 200 includes two accessory equipment racks 230. One of the two accessory equipment racks 230 is provided with a power supply module 231 and a power distribution module 232, and the other accessory equipment rack 230 is provided therein with a fire control module 233 and a monitoring module 234. The power supply module 231 supplies electric power required by the longitudinal rack row 200. The power distribution module 232 distributes the electric power supplied by the power supply module 231 according to a power requirement of the longitudinal rack row 200. The monitoring module 234 is configured to monitor an operation state of the server rack 210. The fire control module 233 is configured to provide a fire alert and fire-fighting measures if there is an emergency occurring in the elongate container 100.

The server rack 210 is usually operated from the front side thereof, so in the present embodiment, the elongate container 100 includes a maintenance door 140 communicating with the cold aisle 101, and thereby facilitating entry and exit of the maintenance staff into and from the elongate container 100 for working on the server rack 210.

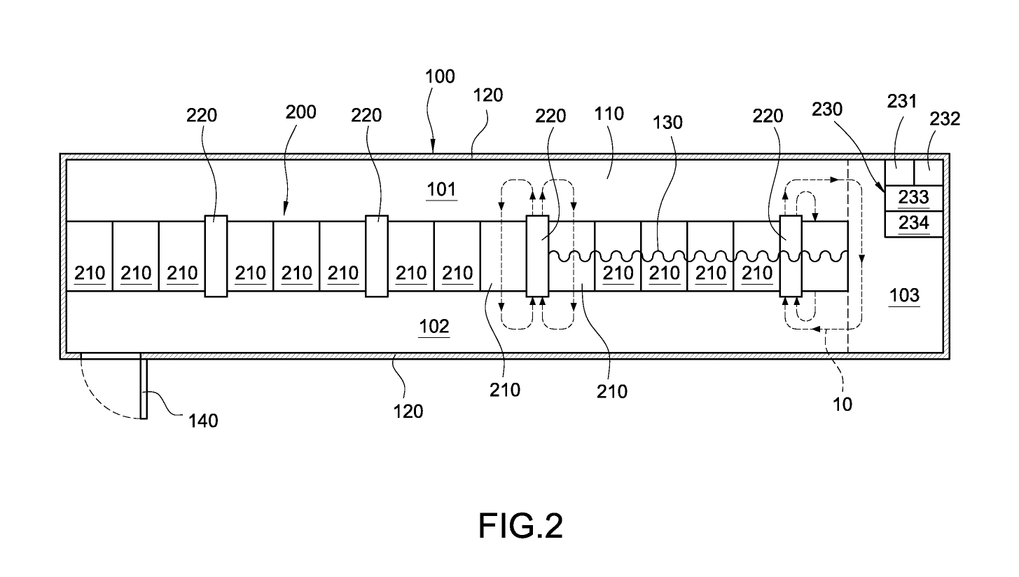

Referring to FIG. 2, a second embodiment of the present invention provides a container-type data center which comprises an elongate container 100 and a longitudinal rack row 200 disposed in the elongate container 100.

According to the present embodiment, the elongate container 100 is preferably a standard-sized container; however, the present invention is not limited thereto, so the standard-sized container may be altered partially as required. The elongate container 100 includes a base 110 and two side walls 120. The base 110 is made of metal and has a flat rectangular shape. The base 110 is disposed horizontally to support the longitudinal rack row 200. Each of the side walls 120 is a rectangular metallic plate and disposed vertically on a respective long side of the base 110, so that the side walls 120 are disposed parallel to and spaced from each other. A top of the elongate container 100 is closed, and two ends of the elongate container 100 can be closed by metallic plates or container doors; however, the present invention is not limited thereto.

The longitudinal rack row 200 is disposed in the elongate container 100. The longitudinal rack row 200 is disposed on the base 110 of the elongate container 100 and is a single row disposed along a longitudinal direction of the elongate container 100. Each of two sides of the longitudinal rack row 200 is spaced from a corresponding one of the two side walls of the elongate container 100, and a cold aisle 101 and a hot aisle 102 are respectively formed between each of the two sides of the longitudinal rack row 200 and a corresponding one of the two side walls 120. One end of the longitudinal rack row 200 extends to one end of the elongate container 100. A single communication channel 103 is formed between the other end of the longitudinal rack row 200 and the other end of the elongate container 100. The cold aisle 101 and the hot aisle 102 are separated from each other, and the cold aisle 101 communicates with the hot aisle 102 only via the communication channel 103. A top of the longitudinal rack row 200 can extend to the top of the elongate container 100. An isolation structure 130 is disposed in a gap between the top of the longitudinal rack row 200 and the top of the elongate container 100. The isolation structure 130 separates the air in the cold aisle 101 from the air in the hot aisle 102. The isolation structure 130 is preferably a partition screen; however, the present invention is not limited thereto, and the isolation structure 130 may be, for example, a partition plate.

The longitudinal rack row 200 includes at least one server rack 210 and at least one air conditioner rack 220. In the present embodiment, the longitudinal rack row 200 includes a plurality of the server racks 210 and a plurality of the air conditioner racks 220 disposed between the server racks 210 and spaced from each other. A heat dissipation fan (not illustrated) is disposed in each of the server racks 210 for drawing in air from a front side of the server rack 210 to cool the server rack 210 and exhausting heated air from a rear side of the server rack 210. The front side of each of the server racks 210 is disposed in the cold aisle 101 and the rear side of each of the server racks 210 is disposed in the hot aisle 102. The air conditioner rack 220 is configured to draw in from the hot aisle 102 the heated air exhausted out of the server rack 210, cool the heated air, and exhaust the cooled air to the cold aisle 101 for the server rack 210 to draw in the cooled air to cool the server rack 210.

According to the present embodiment, the air conditioner rack 220, most adjacent to the communication channel 103 in the elongate container 100, exhausts the cooled air to the cold aisle 101. A portion of the cooled air is drawn into the server rack 210, and other portions of the cooled air flows back to the hot aisle 102 through the communication channel 103 and together with the heated air exhausted out of the server rack 210 are drawn into the air conditioner rack 220 to form an isolation flow field 10. The isolation flow field 10 is configured to separate the cooled air in the cold aisle 101 from the heated air in the hot aisle 102, thereby preventing that the cooled air in the cold aisle 102 directly contacts the heated air in the hot aisle 102 to perform heat exchange.

According to the present invention, in addition to the longitudinal rack row 200, a power supply module 231, a power distribution module 232, a fire control module 233, and a monitoring module 234 are disposed in the elongate container 100. The power supply module 231 supplies electric power required by the longitudinal rack row 200. The power distribution module 232 distributes the electric power supplied by the power supply module 231 according to a power requirement of the longitudinal rack row 200. The monitoring module 234 is configured to monitor an operation state of the server rack 210. The fire control module 233 is configured to provide a fire alert and fire-fighting measures if there is an emergency occurring in the elongate container 100.

Since the cold aisle 101 is full of the cooled air cooled by the air conditioner rack 220, the elongate container 100 of the present embodiment 100 includes a maintenance door 140 communicating with the hot aisle 102 so as to facilitate entry and exit of maintenance staff into and from the elongate container 100, thus preventing the cooled air from leaking out to increase the operation load of the air conditioner rack 220 due to entry and exit of the maintenance staff into and from the elongate container 100.

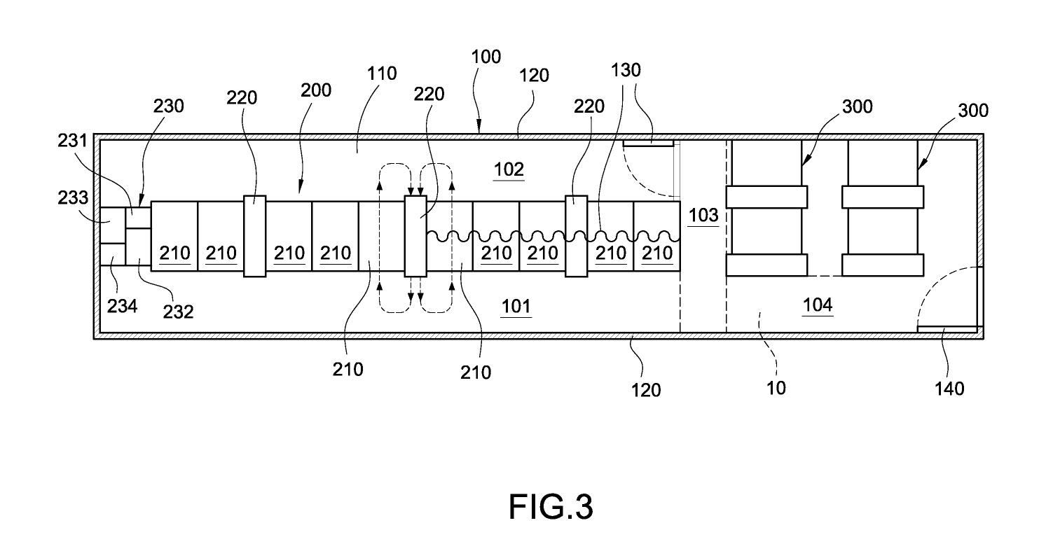

Referring to FIG. 3, a third embodiment of the present invention provides a container-type data center which comprises an elongate container 100 and a longitudinal rack row 200 and two transverse rack columns disposed in the elongate container 100.

According to the present embodiment, the elongate container is preferably a standard-sized container; however, the present invention is not limited thereto, so the standard-sized container may be altered partially as required. The elongate container 100 includes a base 110 and two side walls 120. The base 110 is made of metal and has a flat rectangular shape. The base 110 is disposed horizontally to support the longitudinal rack row 200 and the transverse rack columns 300. Each of the side walls 120 is a rectangular metallic plate and disposed vertically on a respective long side of the base 110, so that the side walls 120 are disposed parallel to and spaced from each other. A top of the elongate container 100 is closed, and two ends of the elongate container 100 can be closed by metallic plates or container doors; however, the present invention is not limited thereto.

In order to enhance the cooling efficiency, the longitudinal rack row 200 and the transverse rack columns 300 can be arranged in different divisions according to different power for division management. The longitudinal rack row 200 and the transverse rack columns 300 are disposed on the base 110 of the elongate container 100. The longitudinal rack row 200 is a single row disposed along a longitudinal direction of the elongate container 100. The transverse rack columns 300 are two rows disposed alongside each other at one end of the elongate container 100 along a transverse direction thereof. The transverse rack columns 300 and the elongate container 100 surround to form a maintenance aisle 104 for maintenance of the longitudinal rack row 200 by maintenance staff. Each of two sides of the longitudinal rack row 200 is spaced from a corresponding one of the two side walls of the elongate container 100, and a cold aisle 101 and a hot aisle 102 are respectively formed between each of the two sides of the longitudinal rack row 200 and a corresponding one of the two side walls 120. One end of the longitudinal rack row 200 extends to the other end of the elongate container 100. A single communication channel 103 is formed between the other end of the longitudinal rack row 200 and the most adjacent transverse rack column 300. The cold aisle 101 and the hot aisle 102 are separated from each other, and the cold aisle 101 communicates with the hot aisle 102 only via the communication channel 103. A top of the longitudinal rack row 200 can extend to the top of the elongate container 100. An isolation structure 130 is disposed in a gap between the top of the longitudinal rack row 200 and the top of the elongate container 100. The isolation structure 130 separates the air in the cold aisle 101 from the air in the hot aisle 102. The isolation structure 130 is preferably a partition screen; however, the present invention is not limited thereto, and the isolation structure 130 may be, for example, a partition plate.

The longitudinal rack row 200 includes at least one server rack 210 and at least one air conditioner rack 220. In the present embodiment, the longitudinal rack row 200 includes a plurality of the server racks 210 and a plurality of the air conditioner racks 220 disposed between the server racks 210 and spaced from each other. A heat dissipation fan (not illustrated) is disposed in each of the server racks 210 for drawing in air from a front side of the server rack 210 to cool the server rack 210 and exhausting heated air from a rear side of the server rack 210. The front side of each of the server racks 210 is disposed in the cold aisle 101, and the rear side of each of the server racks 210 is disposed in the hot aisle 102. The air conditioner rack 220 is configured to draw in from the hot aisle 102 the heated air exhausted out of the server rack 210, cool the heated air, and exhaust the cooled air to the cold aisle 101 for the server rack 210 to draw in the cooled air to cool the server rack 210.

In the present embodiment, an isolation structure 130 is disposed in the communication channel 103. The isolation structure 130 separates the cooled air in the cold aisle 101 from the heated air in the hot aisle 102. The isolation structure 130 can be disposed at a common boundary between the communication channel 103 and the hot aisle 102 or can be disposed at a common boundary between the communication channel 103 and the cold aisle 101. In the present embodiment, the isolation structure 130 can be a partition door; however, the present invention is not limited thereto. Such configuration prevents that the cooled air in the cold aisle 101 comes into contact with the heated air in the hot aisle 102 to perform heat exchange, thereby maintaining the air circulation between the cold aisle 101 and the hot aisle 102.

In the present embodiment, in addition to the longitudinal rack row 200, a power supply module 231, a power distribution module 232, a fire control module 233, and a monitoring module 234 are disposed in the elongate container 100. The power supply module 231 supplies electric power required by the longitudinal rack row 200 and the transverse rack column 300s. The power distribution module 232 distributes the electric power supplied by the power supply module 231 according to a power requirement of the longitudinal rack row 200 and the transverse rack columns 300. The monitoring module 234 is configured to monitor an operation state of the server rack 210. The fire control module 233 is configured to provide a fire alert and fire-fighting measures if there is an emergency occurring in the elongate container 100.

In the present embodiment, the elongate container 100 includes a maintenance door 140 communicating with the maintenance aisle 104 so as to facilitate entry and exit of maintenance staff into and from the elongate container 100, thus preventing the air circulation between the cold aisle 101 and the hot aisle 102 from being effected by entry and exit of the maintenance staff into and from the elongate container 100.

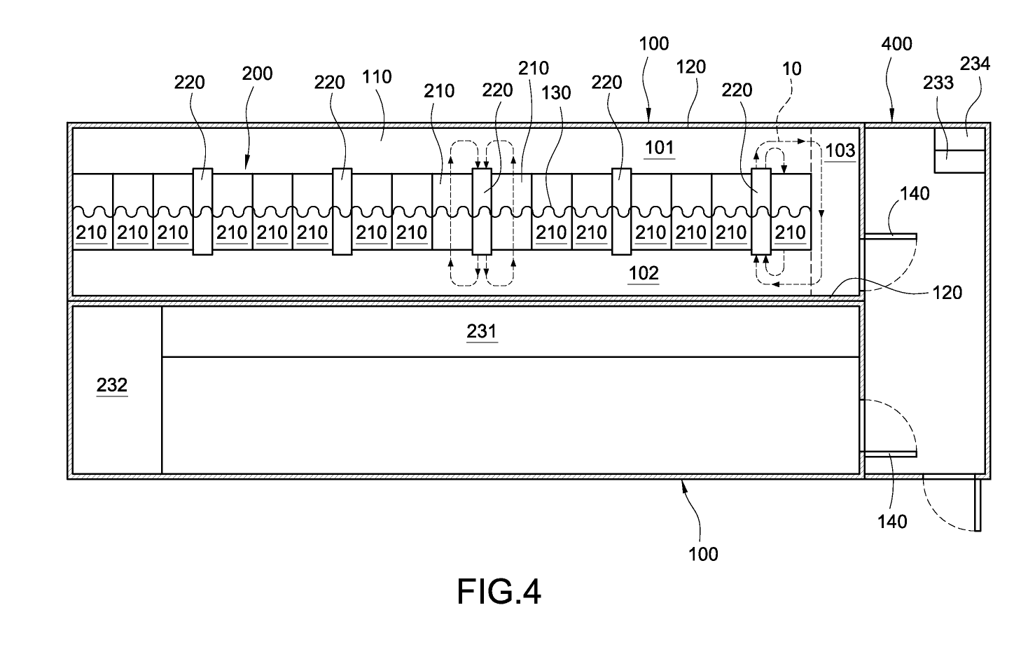

Referring to FIG. 4, a fourth embodiment of the present invention provides a container-type data center which comprises two elongate containers 100, a longitudinal rack row disposed in one of the two elongate containers 100, and a compartment 400.

According to the present embodiment, each elongate container 100 is preferably a standard-sized container; however, the present invention is not limited thereto, so the standard-sized container may be altered partially as required. Each elongate container 100 includes a base 110 and two side walls 120. The base 110 is made of metal and has a flat rectangular shape. The base 110 is disposed horizontally. Each of the side walls 120 is a rectangular metallic plate and disposed vertically on a respective long side of the base 110, so that the side walls 120 are disposed parallel to and spaced from each other. A top of the elongate container 100 is closed, and two ends of the elongate container 100 can be closed by metallic plates or container doors; however, the present invention is not limited thereto.

The longitudinal rack row 200 is contained in one of the elongate containers 100. The longitudinal rack row 200 is disposed on the base 110 of this elongate container 100 and is a single row disposed along a longitudinal direction of this elongate container 100. Each of two sides of the longitudinal rack row 200 is spaced from a corresponding one of the two side walls of the elongate container 100, and a cold aisle 101 and a hot aisle 102 are respectively formed between each of the two sides of the longitudinal rack row 200 and a corresponding one of the two side walls 120. One end of the longitudinal rack row 200 extends to one end of the elongate container 100. A single communication channel 103 is formed between the other end of the longitudinal rack row 200 and the other end of the elongate container 100. The cold aisle 101 and the hot aisle 102 are separated from each other, and the cold aisle 101 communicates with the hot aisle 102 only via the communication channel 103. A top of the longitudinal rack row 200 can extend to the top of the elongate container 100. An isolation structure 130 is disposed in a gap between the top of the longitudinal rack row 200 and the top of the elongate container 100. The isolation structure 130 separates the air in the cold aisle 101 from the air in the hot aisle 102. The isolation structure 130 is preferably a partition screen; however, the present invention is not limited thereto, and the isolation structure 130 may be, for example, a partition plate.

The longitudinal rack row 200 includes at least one server rack 210 and at least one air conditioner rack 220. In the present embodiment, the longitudinal rack row 200 includes a plurality of the server racks 210 and a plurality of the air conditioner racks 220 disposed between the server racks 210 and spaced from each other. A heat dissipation fan (not illustrated) is disposed in each of the server racks 210 for drawing in air from a front side of the server rack 210 to cool the server rack 210 and exhausting heated air from a rear side of the server rack 210. The front side of each of the server racks 210 is disposed in the cold aisle 101, and the rear side of each of the server racks 210 is disposed in the hot aisle 102. The air conditioner rack 220 is configured to draw in from the hot aisle 102 the heated air exhausted out of the server rack 210, cool the heated air, and exhaust the cooled air to the cold aisle 101 for the server rack 210 to draw in the cooled air to cool the server rack 210.

In the present embodiment, the air conditioner rack 220, most adjacent to the communication channel 103 in the elongate container 100, exhausts the cooled air to the cold aisle 101. A portion of the cooled air is drawn into the server rack 210. Other portions of the cooled air flow back to the hot aisle 102 through the communication channel 103 and are drawn into the air conditioner rack 220 to form an isolation flow field 10. The isolation flow field 10 is configured to separate the cooled air in the cold aisle 101 from the heated air in the hot aisle 102, thereby preventing that the cooled air in the cold aisle 101 directly contacts the heated air in the hot aisle 102 to perform heat exchange.

Since the cold aisle 101 is full of the cooled air cooled by the air conditioner rack 220, in the present embodiment one end of the elongate container 100 includes a maintenance door 140 communicating with the communication channel 103 so as to facilitate entry and exit of maintenance staff into and from the elongate container 100, thus preventing the air circulation between the cold aisle 101 and the hot aisle 102 from being effected by entry and exit of the maintenance staff to and from the elongate container 100.

According to the present embodiment, the other elongate container 100 is disposed with a maintenance door 140 at one end thereof and is provided therein with a power supply module 231 and a power distribution module 232. The power supply module 231 supplies electric power required by the longitudinal rack row 200. The power distribution module 232 distributes the electric power supplied by the power supply module 231 according to a power requirement of the longitudinal rack row 200.

In the present embodiment, two elongate containers 100 are arranged alongside each other. The compartment 400 is disposed at one side of the two elongate containers 100. The maintenance door 140 of each of the elongate containers 100 communicates with the compartment 400. A fire control module 233 and a monitoring module 234 are disposed in the compartment 400. The monitoring module 234 is configured to monitor an operation state of the server rack 210. The fire control module 233 is configured to provide a fire alert and fire-fighting measures if there is an emergency occurring in the elongate container 100.

In the container-type data center, the cold aisle 101, the hot aisle 102, and the communication channel 103 communicating with the cold aisle 101 and the hot aisle 102 are formed by disposing the longitudinal rack row 200 in the elongate container 100. The maintenance staff can move between the cold aisle and the hot aisle via the communication channel 103, thereby reducing the frequency of opening the maintenance door 140 of the elongate container 100 during maintenance operations, thus preventing the air circulation between the cold aisle 101 and the hot aisle 102 from being effected by the ambient environment.

As mentioned above, in the container-type data center of the present invention, the single longitudinal rack row 200 is used to form in the elongate container 100 the cold aisle 101, the hot aisle 102, and the communication channel 103 communicating the cold aisle 101 and the hot aisle 102. Therefore, efficient space planning can be acquired in the limited space of the elongate container 100 to facilitate better management on an air-circulation field for heat dissipation and to allow easy maintenance.

It is to be understood that the above descriptions are merely preferable embodiments of the present invention and not intended to limit the scope of the present invention. Equivalent changes and modifications made in the spirit of the present invention are regarded as falling within the scope of the present invention.

What is claimed is:

1. A container-type data center, comprising an elongate container and a single longitudinal rack row disposed in the elongate container, the elongate container including two side walls, the longitudinal rack row being disposed along a longitudinal direction of the elongate container, a cold aisle and a hot aisle being respectively formed between each of two sides of the longitudinal rack row and a corresponding one of the two side walls, the longitudinal rack row forming a single communication channel communicating the cold aisle with the hot aisle, the longitudinal rack row including at least one server rack and at least one air conditioner rack.

2. The container-type data center of claim 1, wherein the air conditioner rack is configured to draw in air from the hot aisle, cool the air, and exhaust the cooled air to the cold aisle.

3. The container-type data center of claim 2, wherein the air conditioner rack is disposed relatively adjacent to the communication channel in the elongate container, a portion of the air exhausted to the cold aisle flows back to the hot aisle through the communication channel and is again drawn into the air conditioner rack to form an isolation flow field, and the isolation flow field is configured to separate the air in the cold aisle from the air in the hot aisle.

4. The container-type data center of claim 2, wherein the air conditioner rack is disposed relatively adjacent to the communication channel in the elongate container, a portion of the air exhausted to the cold aisle flows back to the hot aisle through the communication channel and together with the hot air exhausted from the adjacent server rack are drawn into the air conditioner rack to form an isolation flow field, and the isolation flow field is configured to separate the air in the cold aisle from the air in the hot aisle.

5. The container-type data center of claim 1, wherein an isolation structure is disposed in the communication channel, and the isolation structure separates the air in the cold aisle from the air in the hot aisle.

6. The container-type data center of claim 1, wherein an isolation structure is disposed between a top of the server rack row and a top of the elongate container, and the isolation structure separates the air in the cold aisle from the air in the hot aisle.

7. The container-type data center of claim 5, wherein the isolation structure is a partition screen or a partition door.

8. The container type data center of claim 6, wherein the isolation structure is a partition door.

9. The container-type data center of claim 1, wherein the longitudinal rack row includes an accessory equipment rack, the accessory equipment rack is provided with a power supply module, and the power supply module supplies electric power required by the longitudinal rack row.

10. The container-type data center of claim 9, wherein the accessory equipment rack is provided with a power distribution module, and the power distribution module distributes the electric power supplied by the power supply module according to a power requirement of the longitudinal rack row.

11. The container-type data center of claim 9, wherein the longitudinal rack row includes another accessory equipment rack provided with a power distribution module, and the power distribution module distributes the electric power supplied by the power supply module according to a power requirement of the longitudinal rack row.

12. The container-type data center of claim 1, wherein the longitudinal rack row includes an accessory equipment rack, and the accessory equipment rack is provided with a monitoring module.

13. The container-type data center of claim 1, wherein the longitudinal rack row includes an accessory equipment rack, and the accessory equipment rack is provided with a fire control module.

14. The container-type data center of claim 1, wherein a transverse rack column is further disposed in the elongate container, and a maintenance aisle is formed between the transverse rack column and any of the side walls.

15. The container-type data center of claim 14, wherein the elongate container is provided with a maintenance door communicating with the maintenance aisle for entering and exiting the elongate container.

16. The container-type data center of claim 1, wherein the elongate container is provided with a maintenance door communicating with the cold aisle for entering and exiting the elongate container.

17. The container-type data center of claim 1, wherein the elongate container is provided with a maintenance door communicating with the hot aisle for entering and exiting the elongate container.

18. The container-type data center of claim 1, wherein the elongate container is provided with a maintenance door communicating with the communication channel for entering and exiting the elongate container.

19. The container-type data center of claim 1, wherein the communication channel is disposed at one end of the longitudinal rack row.

20. The container-type data center of claim 1, wherein the communication channel is disposed in a middle portion of the longitudinal rack row.
